(19) United States
(12) Patent Application Publication
(10) Pub. No.: US 2025/0011971 A1
(43) Pub. Date: Jan. 9, 2025

(54) GROUP III NITRIDE SINGLE CRYSTAL SUBSTRATE PRODUCING METHOD, AND ALUMINUM NITRIDE SINGLE CRYSTAL SUBSTRATE

(71) Applicant: TOKUYAMA CORPORATION, Shunan-shi, Yamaguchi (JP)

(72) Inventors: Masayuki FUKUDA, Shunan-shi (JP); Tatsuya HITOMI, Shunan-shi (JP); Reo YAMAMOTO, Shunan-shi (JP)

(73) Assignee: TOKUYAMA CORPORATION, Shunan-shi, Yamaguchi (JP)

(21) Appl. No.: 18/708,259

(22) PCT Filed: Dec. 8, 2022
(86) PCT No.: PCT/JP2022/045324

§ 371 Date: May 8, 2024

(30) Foreign Application Priority Data
Dec. 27, 2021 (JP) 2021-212120

(51) Int. Cl. C30B 33/00; B24B 7/22; B28D 5/00; B28D 5/04; C30B 29/40

(52) U.S. Cl. CPC C30B 33/00; B24B 7/22; B28D 5/0082; B28D 5/045; C30B 29/403

(57) ABSTRACT

A method of producing a group III nitride single crystal substrate includes: processing a face of a group III nitride single crystal layer of a layered body, so that the face is parallel to a crystal lattice plane, the layered body including a base substrate, and the group III nitride single crystal layer over the base substrate; after said processing, cutting and separating a group III nitride single crystal in a form of plate from the base substrate or the group III nitride single crystal layer, or cutting and separating the base substrate and the group III nitride single crystal layer on an interface therebetween in a form of plate; and after said cutting and separating, polishing a cut surface of the group III nitride single crystal, the cut surface being formed by said cutting.

### TECHNICAL FIELD

The present invention relates to group III nitride single crystal substrates.

### BACKGROUND ART

Group III nitride single crystal substrates that are single crystal substrates made from group III nitrides such as aluminum nitride, gallium nitride and indium nitride are useful as the substrates for electronic devices such as deep ultraviolet light emitting devices and high voltage Schottky diodes. Patent literature 1 discloses a method of producing an aluminum nitride single crystal substrate.

Patent literature 1 discloses that an aluminum source and a nitrogen source are supplied onto a main face of a base substrate made from an aluminum nitride single crystal to grow an aluminum nitride single crystal layer over the main face, and thereafter, the base substrate and the aluminum nitride single crystal layer are separated. This separation is performed by cutting an aluminum nitride single crystal layer portion of the layered body, and thereby, separating the layered body into: the base substrate and a thin film that is at least part of the aluminum nitride single crystal layer and that is layered over the base substrate; and any other part of the aluminum nitride single crystal layer.

### CITATION LIST

### Patent Literature

Patent Literature 1: WO 2017/164233 A1

### SUMMARY OF INVENTION

### Technical Problem

A single crystal substrate obtained in such a way has a low crystal lattice distortion, and a high flatness in crystal lattice plane, whereas the surface profile thereof may have a large warp. A large warp of the surface profile of a single crystal substrate causes a yield to drop because causing pattern misalignment in the process of forming an electronic device, causing thickness nonuniformity in the process of forming a light emitting device layer, etc., or the like. Further, a large warp destabilizes picking-up of a back face when the single crystal substrate is transferred, which causes the substrate to break during transfer.

Any method for solving formation of such a warp by grinding and/or polishing is used. However, such a method cannot solve a warp enough, or, in view of the material removal amount for grinding and/or polishing, requires a larger amount of a design thickness of the single crystal layer grown over the main face of the base substrate.

An object of the present invention is to provide a method of producing a group III nitride single crystal substrate which can suppress formation of a warp. Another object of the present invention is to provide an aluminum nitride single crystal substrate having a warp of a less degree.

### Solution to Problem

In order to solve the above problems, the inventors researched and examined the causes of formation of a warp. As a result of the examination, the causes of formation of a warp are illustrated in FIG. 4. FIG. 4 illustrates the flow of a conventional method of producing a group III nitride single crystal substrate S20 (which hereinafter may be referred to as a “producing method S20”), and shows each step (steps S21 to S24) with the schematic views illustrating the steps included.

In step S21, a layered body 20 fixed to a jig 24 via an adhesive 23 is cut with a wire saw 25. Here, the layered body 20 is formed of a base substrate 21 on the adhesive 23 side, and a group III nitride single crystal layer 22 grown over the base substrate 21. S_{g} shows a growth surface, and Sₖ shows one crystal lattice plane. In this step, the group III nitride single crystal layer 22 is cut with the wire saw 25 in the direction parallel to the surface of the jig 24, so that part thereof is separated from the base substrate 21. Thereby, a single crystal 22a that is the separated part of the group III nitride single crystal layer 22 is obtained.

However, cutting exactly parallel to the crystal lattice plane Sₖ with the wire saw 25 is difficult. Further, when either the front or back face of the group III nitride single crystal layer 22 is a polar face, the wire saw 25 tends to move toward either of the faces during the cutting. In particular, the path of the wire saw 25 in cutting is presumed to move toward a chemically and/or physically unstable face because such an unstable face is easily ground. For example, when the front face of the group III nitride single crystal layer 22 is a stable face and the back face thereof is an unstable face, a cut surface that is on the surface side is an unstable face, and thus, the wire saw 25 is presumed to move to the surface side.

A face Sₑ of the single crystal 22a which is on the cutting side curves (warps due to deviation of the wire saw 25 in cutting, and the Twyman effect (the phenomenon such that a processed damaged layer warp as if expanding. The processed face affects the shape change). The crystal lattice plane Sₖ is in a curved form due to the Twyman effect.

In step S22, the obtained single crystal 22a is fixed to the jig 24 via the adhesive 23, and the curved face S_{c} on the cutting side is ground (a polishing step may be included after the grinding, which may be hereinafter referred to as “grinding and/or polishing”) to be flattened to form a face S_{c}′. At this time, the growth surface S_{g} of the single crystal 22a is arranged on the adhesive 23 side and fixed to the jig 24 in this schematic view because preferably, a face that is necessary to be finished to be an epi-ready mirror face is polished at last. In this state, the crystal lattice plane Sₖ still curves.

In step S23, the face S_{c}′ of the single crystal 22a obtained in step S22 is fixed to the jig 24 via the adhesive 23, the growth surface S_{g} having convexes and concaves is flattened by grinding and/or polishing to form a face S_{g}′. Thereby, the single crystal 22a forms a single crystal substrate (which may be hereinafter referred to as a “self-supporting substrate”) 22b. The front and back faces (faces S_{g}′ and S_{c}′) of the single crystal substrate 22b are parallel. The crystal lattice plane Sₖ still curves in the state where the single crystal 22a is fixed to the jig 24 with the polished face S_{c}′ arranged on the adhesive 23 side.

In step S24, the obtained single crystal substrate 22b is removed from the jig 24 and the adhesive 23. It is considered that in the conventional art, the single crystal substrate 22b curves and warps, so that the front and back faces (faces S_{g}′ and S_{c}′) curve as shown in FIG. 4 because when this single crystal substrate 22b is removed from the jig 24 and the adhesive 23, the crystal lattice plane Sₖ will be flat since both the faces of the single crystal substrate 22b are mirror faces, there is almost no curve due to the Twyman effect on the substrate, and in addition, the crystal lattice plane Sₖ of the self-supporting substrate 22b still curves in step S23.

Specific means for solving the foregoing were provided based on the foregoing idea, and thereby, the present invention was completed. Specifically, see the following.

The present application discloses a method of producing a group III nitride single crystal substrate which comprises: processing a face of a group III nitride single crystal layer of a layered body, so that the face is parallel to a crystal lattice plane, the layered body including a base substrate, and the group III nitride single crystal layer over the base substrate; after said processing, cutting and separating a group III nitride single crystal in a form of plate from the base substrate or the group III nitride single crystal layer, or cutting and separating the base substrate and the group III nitride single crystal layer on an interface therebetween in a form of plate; and after said cutting and separating, polishing a cut surface of the group III nitride single crystal, the cut surface being formed by said cutting.

In the producing method, said processing may comprise: fixing the group III nitride crystal, so that a radius of curvature of the crystal lattice plane is at least 15 m, and grinding a fixed growth surface of the group III nitride single crystal layer.

A face obtained by said polishing may be parallel to the crystal lattice plane.

A radius of curvature of the crystal lattice plane before said cutting and separating may be at least 50 m.

The group III nitride single crystal layer may be an aluminum nitride single crystal layer, and the face processed in the producing method may be an aluminum-polar face.

In said cutting and separating, the layered body may be cut in the form of plate by means of one cutting jig.

In said polishing, because a flat growth surface S_{g}′ and a crystal lattice plane Sₖ are parallel, one may fix the growth surface S_{g}′ of the group III nitride single crystal, so that the crystal lattice plane is flat, and may polish the cut surface.

The present application discloses an aluminum nitride single crystal substrate, wherein difference between difference in height of a surface of the aluminum nitride single crystal substrate, and difference in height of a crystal lattice plane is at most 15 μm, the difference in height of a surface being calculated from a radius of curvature of the surface, the difference in height of a crystal lattice plane being calculated from a radius of curvature of the crystal lattice plane, and a concentration of carbon contained as an impurity is at most 3×10¹⁷ atoms/cm³. At this time, the radius of curvature of the crystal lattice plane may be at least 15 m.

A thickness of the aluminum nitride single crystal substrate may be at least 250 μm.

The surface of the aluminum nitride single crystal substrate may be an aluminum-polar face.

### Effects of Invention

According to the present disclosure, a group III nitride single crystal substrate having a warp of a suppressed degree can be provided.

### BRIEF DESCRIPTION OF DRAWINGS

FIG. 1 illustrates each step of a producing method S10 according to one embodiment.

FIG. 2 illustrates a warp of a group III nitride single crystal substrate.

FIG. 3 schematically shows a state of the group III nitride single crystal substrate viewed from the side.

FIG. 4 illustrates each step of a conventional producing method S20.

### DESCRIPTION OF EMBODIMENTS

Hereinafter embodiments of the present disclosure will be described with reference to the drawings. The present disclosure is not limited to these embodiments. The drawings do not always show exact dimensions. Some reference signs may be omitted in the drawings.

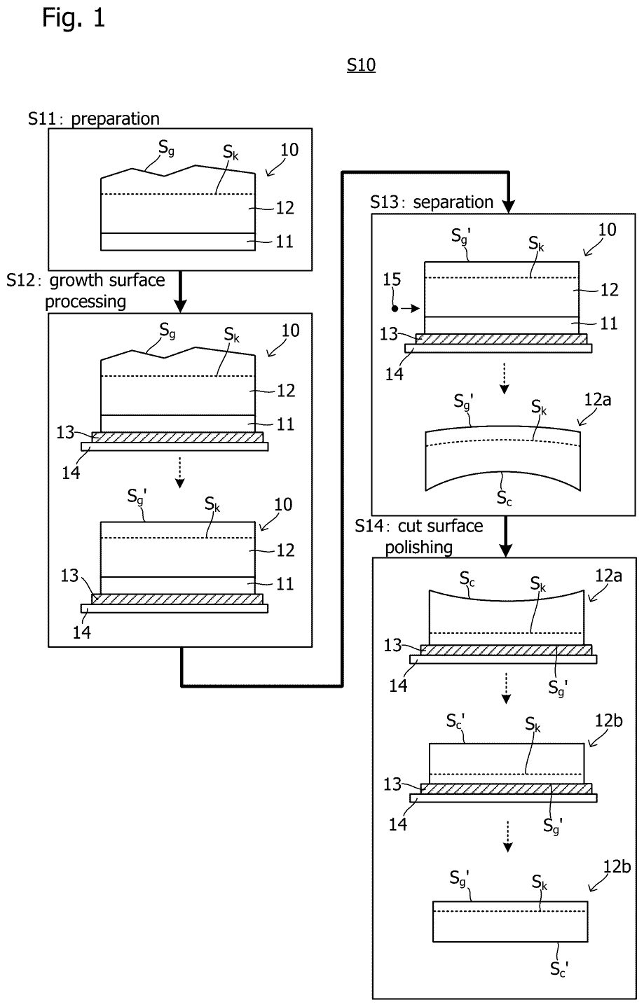

1. Method of Producing Group III Nitride Single Crystal Substrate S10 FIG. 1 illustrates the flow of a method of producing a group III nitride single crystal substrate S10 according to one aspect of the present disclosure (which may be hereinafter referred to as a “producing method S10”). FIG. 1 shows each step (steps S11 to S14) with the schematic views illustrating the steps included.

Here, among group III nitride single crystal substrates, an aluminum nitride single crystal substrate will be described as one example. Accordingly, in the following description, an “aluminum nitride single crystal” can be replaced by and considered as any other group III nitride (gallium nitride or indium nitride) single crystal except the case where the matter unique to an aluminum nitride single crystal is described.

### 1.1. Preparation Step S11

Prepared in the preparation step S11 is a layered body 10 such that an aluminum nitride single crystal layer 12 grown and thereby formed over a face of a base substrate 11 is layered.

1.1a. Base Substrate

In this embodiment, the base substrate 11 is made from an aluminum nitride single crystal. A known base substrate may be used as the base substrate 11. For example, the base substrate 11 is as follows.

The face of the base substrate 11 over which the aluminum nitride single crystal layer 12 is to be grown, that is, the main face of the base substrate 11 is not specifically limited. The main face may be on any crystal lattice plane without limitations as long as the aluminum nitride single crystal can be grown thereover because an aluminum nitride single crystal substrate (which may be hereinafter referred to as a “self-supporting substrate”) 12b with a stable quality can be produced. Therefore, for example, the main face may be on a low-index plane such as a (112) plane. In view of usefulness of the aluminum nitride single crystal substrate 12b to be obtained, and in view of easy growth of the aluminum nitride single crystal layer 12, the main face is preferably on a (001) plane (+c plane), a (00-1) plane (−c plane), a (110) plane, or a (100) plane.

The aluminum nitride single crystal layer 12 formed over the main face of the base substrate 11 has a crystal plane index corresponding to the main face of the base substrate 11. That is, when the base substrate 11 having the main face on a (001) plane is prepared, the crystal lattice plane Sₖ of the aluminum nitride single crystal layer 12 is also a (001) plane, and the main face of the aluminum nitride single crystal substrate 12b to be finally obtained is also on a (001) plane. A (001) plane represents a c plane, and when the main face is on this plane, a c plane or a −c plane is regarded as the main face. Similarly, when a (110) plane is used as the main face of the base substrate 11, the crystal lattice plane Sₖ of the aluminum nitride single crystal layer 12, and the main face of the aluminum nitride single crystal substrate 12b to be finally obtained are also on a (110) plane; and when a (100) plane is used as the main face of the base substrate 11, the crystal lattice plane Sₖ of the aluminum nitride single crystal layer, and the main face of the aluminum nitride single crystal substrate 12b to be finally obtained are also on a (100) plane.

When the aluminum nitride single crystal layer 12 of a thick film is formed over the main face of the base substrate 11, the dislocation density in the main face is preferably at most 106 cm⁻². For thickening the aluminum nitride single crystal layer 12, the dislocation density in the main face is more preferably at most 10⁵ cm⁻², further preferably at most 10⁴ cm⁻², and especially preferably at most 10³ cm⁻². The lower the dislocation density is, the more preferable, whereas the lower limit of the dislocation density in the main face is 10 cm⁻² in view of industrial production of the base substrate. The etch pit density value may be substituted for the dislocation density value. An etch pit density is a number average density per unit area measured by: etching an aluminum nitride single crystal substrate in molten alkali hydroxides of sodium hydroxide and potassium hydroxide to form pits at dislocations; counting the number of the pits formed on the surface of the aluminum nitride single crystal substrate by observation by means of an optical microscope; and dividing the number of the counted pits by an observed area.

The shape of the base substrate 11 may be round, or quadrangular, or indefinite; and the area thereof is preferably 100 to 10000 mm². The thickness of the base substrate 11 may be determined within such a range that the base substrate 11 does not break due to insufficient strength when the aluminum nitride single crystal layer 12 is grown; and specifically, is preferably 50 μm to 2000 μm, and more preferably 100 μm to 1000 μm.

Any particular limitations other than the foregoing are not imposed on the main face of the base substrate 11, whereas, preferably, the surface roughness (root mean square roughness) is 0.05 nm to 0.5 nm, and an atomic step is observed using an atomic force microscope or a scanning probe microscope having a field of approximately 2 μm×2 μm. The surface roughness may be adjusted by chemomechanical polishing (CMP). The surface roughness is measured by removing foreign substances and contaminants on the surface of the base substrate, and thereafter, observing a field of 5 μm×5 μm on the surface by means of an atomic force microscope or a scanning prove microscope. The main face of the base substrate may be processed to have an island-like or striped pattern.

The radius of curvature of the main face of the base substrate 11 is not specifically limited, whereas is preferably within the range from 0.1 m to 10000 m, more preferably 2 m to 10000 m, and further preferably 8 m to 10000 m. When the main face of the base substrate 11 is on a (001) plane, a (00-1) plane, a (110) plane, or a (100) plane, the radius of curvature of the crystal lattice plane that forms the main face of the base substrate 11, or the radius of curvature of the crystal lattice plane parallel to the main face is not specifically limited, whereas is preferably within the range from 2 m to 10000 m. When the aluminum nitride single crystal layer 12 is grown to have a thickness of at least 500 μm, cracks may be formed when the thick layer is grown if the radius of curvature of the crystal lattice plane that forms the main face of the base substrate 11, or the radius of curvature of the crystal lattice plane parallel to the main face is short. Therefore, the radius of curvature of the crystal lattice plane is preferably 5 m to 10000 m, and further preferably 10 m to 10000 m.

The aluminum nitride single crystal layer 12 grown over such a base substrate 11 has a good crystal quality.

The base substrate 11 may be grown by either sublimation (physical vapor transport (PVT)) or hydride vapor phase epitaxy (HVPE); or may be grown by a liquid-phase method. As the base substrate 11, a base substrate processed in advance to have an island-like or striped pattern may be used.

1.1b. Aluminum Nitride Single Crystal Layer 12

The aluminum nitride single crystal layer 12 is the layer grown and thereby layered over the base substrate 11, and made from an aluminum nitride single crystal. The thickness of the aluminum nitride single crystal layer 12 is preferably at least 500 μm because the thickness of aluminum nitride single crystal substrate 12b to be obtained is sufficiently secured, and when the aluminum nitride single crystal substrate 12b is processed to be a wafer for manufacturing devices by grinding and/or polishing, the strength of the aluminum nitride single crystal substrate 12b is easily secured.

The upper limit of the thickness of the aluminum nitride single crystal layer 12 is not specifically limited, whereas is 2000 μm in view of industrial production. In view of industrial production, the thickness of the aluminum nitride single crystal layer 12 grown in a growth step is preferably 600 μm to 1500 μm, and further preferably 800 μm to 1200 μm because when the aluminum nitride single crystal layer 12 to be grown is excessively thick, a lot of time is required for the growth step and a polishing step therefor.

The in-plane thickness difference of the aluminum nitride single crystal layer 12 (which shall be the difference in height between the highest and lowest in-plane places of the aluminum nitride single crystal layer 12) affects the processing time for the growth surface processing step according to step S12 in FIG. 1 (which will be described in detail later). Accordingly, the smaller this thickness difference is, the shorter the processing time is, and therefore, the more preferable. In view of industrial production, the in-plane thickness difference of the aluminum nitride single crystal layer 12 is preferably 5 μm to 600 μm, and further preferably 5 μm to 300 μm.

Any of sublimation, a liquid-phase method, and vapor phase growth may be used as the method of growing the aluminum nitride single crystal layer 12. When sublimation is used, the aluminum source is a vapor of sublimated or decomposed aluminum nitride, and the nitrogen source is a vapor of sublimated or decomposed aluminum nitride, or nitrogen gas supplied to a growth apparatus. When a liquid-phase method is used, the aluminum source and the nitrogen source are a solution where aluminum nitride dissolves. When vapor phase growth is used, the aluminum source is an aluminum halide gas such as aluminum chloride, aluminum iodide, and aluminum bromide, and/or an organic aluminum gas such as trimethylaluminum and triethylaluminum; and the nitrogen source is an ammonia gas or a nitrogen gas.

The effect is significant when the aluminum nitride single crystal layer 12 is grown by HVPE, which is one of the methods of vapor phase growth among the foregoing growth method. The growth rate by HVPE is lower than that by sublimation. However, HVPE can lead to a lower concentration of impurities having a bad effect on deep ultraviolet light transmissivity, and therefore, is preferable for producing aluminum nitride single crystal substrates for light emitting device layers. HVPE is also preferable for producing aluminum nitride single crystal substrates for electronic devices because HVPE can lead to reduced impurities, which reduces the density of point defects such as aluminum vacancies that have a bad effect on electron mobility. Specifically, it is easier to lower the concentration of carbon contained as an impurity in the final aluminum nitride single crystal substrate to be at most 3×10¹⁷ atoms/cm³ by HVPE than by any other vapor phase growth. The lower limit of the carbon concentration is not particularly limited, whereas is 1×10¹⁴ atoms/cm³.

HVPE is a producing method that leads to a well-balanced crystal quality and mass productivity because the growth rate thereby is higher than that by a liquid-phase method, and therefore, HVPE allows a single crystal of good crystallinity to be grown at a high deposition rate.

The vapor phase growth apparatus used for HVPE (HVPE apparatus) is not particularly limited, but is as known. In this apparatus, the aluminum nitride single crystal layer is grown by supplying the aluminum source gas and the nitrogen source gas into a reactor, and reacting both the gasses on the heated base substrate 11. As the aluminum source gas, an aluminum halide gas such as aluminum chloride gas, or a mixed gas of an organoaluminum gas and a hydrogen halide gas is used. As the nitrogen source gas, an ammonia gas is preferably used. These raw material gasses are supplied together with a carrier gas such as a hydrogen gas, a nitrogen gas, an argon gas and a helium gas. As the carrier gas, one gas may be individually used, or two or more gases may be used in combination. Further, one may appropriately and additionally supply a halogen-based gas such as a halogen gas and a hydrogen halide gas into the aluminum source gas and the nitrogen source gas to suppress formation of metal aluminum caused by a disproportionation reaction of the aluminum halide gas. In addition to the supply amount of each of these gases, growth conditions such as the shapes of a nozzle and the reactor via and into which the raw material gases are supplied onto the base substrate, the carrier gas composition, the supply amount of the carrier gas, the linear velocity of the gas flow in the reactor, the growth pressure (pressure in the reactor), and the heating temperature of the base substrate (growth temperature) are properly adjusted, and thereby, a good crystal quality is obtained at a desired growth rate. Typical examples of the growth conditions include: 0.1 sccm to 100 sccm in aluminum source gas; 1 sccm to 10000 sccm in nitrogen source gas; 0.1 sccm to 10000 sccm in additionally supplied halogen-based gas; 1000 sccm to 100000 sccm in total carrier gas flow; nitrogen, hydrogen, argon, and helium in carrier gas composition (the gas may have any composition ratio); 36 Torr to 1000 Torr in growth pressure; and 1200° C. to 1800° C. in heating temperature of the base substrate (growth temperature).

Various studies have been made on methods using HVPE for obtaining a single crystal of good crystallinity. In the present invention, such a known method may be used without any specific limitation. Among them, preferably, an aluminum halide gas with a reduced content of an aluminum monohalide gas (the major component is an aluminum trihalide gas) is used as a raw material gas. An aluminum trihalide gas with a high content of an aluminum monohalide gas may lead to a lower crystal quality. Therefore, preferably, a method such that an aluminum monohalide gas contained in the aluminum source gas is as little as possible is used.

Such a method may be also used: the base substrate is processed in advance to have an island-like or striped pattern to limit the growth portion of the aluminum nitride single crystal layer at the initial growth stage. In such a growth method, independent aluminum nitride single crystals grow from respective convexes on the surface of the base substrate right above or oblique above. In due course, independent aluminum nitride single crystals grown from adjacent convexes come into contact with each other, and finally a thick film of the single aluminum nitride single crystal grows.

When it is necessary to control the conductivity of the aluminum nitride single crystal layer 12, the aluminum nitride single crystal layer may be grown while impurities that form donors and/or acceptors (such as compounds containing Si, Mg, S, etc.) are properly supplied.

1.1c. Layered Body 10

As the above, prepared in the preparation step S11 is the layered body 10 such that the aluminum nitride single crystal layer 12 is layered on the base substrate 11. As shown in FIG. 1, in such a layered body, the face of the aluminum nitride single crystal layer 12 on the opposite side of the base substrate 11 is what is called a growth surface (which shall be an aluminum-polar face in this embodiment) S_{g}, that is, the surface is not always flat.

As indicated by Sₖ in FIG. 1, the crystal lattice plane Sₖ parallel to the main face of the base substrate 11 is formed in the aluminum nitride single crystal layer 12.

At this time point (immediately after the aluminum nitride single crystal layer 12 is layered over the base substrate 11, and before the following growth surface processing step S12, which may be hereinafter referred to as an “as-grown” time point), the radius of curvature of the crystal lattice plane Sₖ is preferably at least 50 m.

### 1.2. Growth Surface Processing Step S12

The growth surface processing step S12 is the step of processing the face of the group III nitride single crystal layer of the layered body that includes the group III nitride single crystal layer obtained in the preparation step S11 to be parallel to the main face. As a more specific example, in the layered body 10 obtained in the preparation step S11, the growth surface S_{g} of the aluminum nitride single crystal layer 12 is ground to flatten. Polishing may be also performed after the grinding. The growth surface S_{g} can be flattened only by polishing without grinding. However, polishing only requires more processing time than grinding. Therefore, grinding is preferably included.

Here, the reason why the surface is flattened not by cutting but by grinding and optionally polishing in this step is because more excellent processing in flatness and parallelism can be carried out by grinding and optionally polishing than by cutting.

In the growth surface processing step S12, prior to polishing, the layered body 10 is fixed to a jig 14 via an adhesive 13. At this time, the adhesive 13 is arranged on a supporting surface of the jig 14. Here, in the layered body 10, the face of the base substrate 11 which is the opposite to the side where the aluminum nitride single crystal layer 12 is layered is directed to come into contact with the adhesive 13.

The fixing method may be appropriately selected in view of the difference in height on the face fixed to the jig 14 in the layered body 10, so that the radius of curvature of the crystal lattice plane Sₖ when fixed is at least 15 m. At this time, a known method or device may be used as a fixing means. For example, when the difference between the difference in height on the surface of the fixed face for fixing the layered body 10 having a diameter of 50.8 mm, and the difference in height on the crystal lattice plane is at most 21 μm, preferably, the fixed face of the layered body 10 is adhered so as to be in parallel to the supporting surface of the jig. When that difference is larger than 21 μm, it is preferable to adhere the fixed face of the layered body 10 as the shape of the fixed face is maintained. When the radius of curvature of the crystal lattice plane of the layered body 10 after the fixing which is expected from the difference in height on the surface of the fixed face for fixing the layered body 10 is smaller than the radius of curvature of the crystal lattice plane at the as-grown time point, it is more preferable to fix the layered body 10 as the shape of the fixed face is maintained even when the aforementioned difference between the differences in height is at most 21 μm because the radius of curvature of the crystal lattice plane of the layered body 10 when fixed is equal to that at the as-grown time point.

The growth surface S_{g} may be fixed to the jig 14 and processed. However, because it is preferable to grind the base substrate 11 as little as possible if the base substrate 11 is repeatedly used, it is preferable to fix the face which is the opposite to the side where the aluminum nitride single crystal layer 12 is layered.

The jig 14 is the jig that retains the layered body 10 in a posture suitable for grinding or polishing (for example, horizontally). Any known glass plate, ceramic plate, metal plate, or the like may be used as the jig 14.

The adhesive 13 retains the layered body 10 on the jig 14 to fix the layered body 10 so that the layered body 10 cannot move even by polishing. A known wax or tape may be used as the adhesive without any specific limitations.

A wax as used herein is not particularly limited. For example, a solid or liquid wax is preferably used in view of easy positioning of the substrate in the fixing operation, and easy releasability with a solvent or the like. A tape as used herein is not particularly limited. For example, a thermal release tape is preferably used in view of easy releasability by heat treatment or the like.

Known conditions may be used for grinding or polishing the growth surface S_{g} of the layered body 10 fixed to the jig 14.

The growth surface S_{g} may be ground using a grindstone such as a diamond wheel. A grinding fluid for either circulating or flowing-away style may be used. The particle size of the grindstone may be selected so that the target grinding rate can be obtained. The smaller the particle size is, the easier the growth surface S_{g} is ground but the larger a processed damaged layer is. The smaller the particle size is, the more difficult the growth surface S_{g} is ground and thus the more easily finishing with the target thickness is achieved, but the longer the processing time is and the lower the productivity is. For example, specifically, #100 to #4000 is preferable, and #200 to #2000 is more preferrable.

As the polishing, chemomechanical polishing (CMP) is preferable. An abrasive containing a material such as silica, alumina, ceria, silicon carbide, boron nitride, and diamond may be used. The properties of the abrasive may be alkaline, neutral, or acidic. Because a nitrogen-polar face (−c place) of aluminum nitride is low alkali-resistant, a weakly alkaline, neutral or acidic abrasive, specifically an abrasive having a pH of at most 9 is more preferably used than a strong alkaline abrasive. A strong alkaline abrasive may be also used without any problem of course when a protection film is formed on the nitrogen-polar face. An additive such as an oxidizing agent may be incorporated into the abrasive in order to improve the polishing rate. A commercially available polishing pad may be used, and the material and hardness thereof are not specifically restricted.

In view of further controlling flatness, and in view of shortening the processing time, grinding is more preferable than polishing as described above.

All the polishing may be carried out by, for example, CMP. For example, when the removal amount by polishing is large, one may adjust the thickness to be approximately a desired thickness in advance by a means offering a high polishing rate such as mirror finish lapping, and thereafter, carry out CMP.

The growth surface S_{g} is flattened by this grinding or polishing to form the growth surface S_{g}′ after processing. In this step, only the growth surface S_{g} is processed. Thus, the crystal lattice plane Sₖ does not change. Therefore, according to this, the crystal lattice plane Sₖ and the growth surface S_{g}′ after processing are in parallel to each other.

In the state where the layered body 10 is fixed to the jig 14 with the adhesive 13, the flatness of the growth surface S_{g}′ after processing is preferably 0 μm to 10 μm, and further preferably 0 μm to 5 μm. Here, the flatness of the growth surface S_{g}′ after processing represents the in-plane deference between the convexes and the concaves of the growth surface S_{g}′ after processing.

### 1.3. Separation Step S13

In the separation step S13, an aluminum nitride single crystal 12a is separated by cutting part of the aluminum nitride single crystal layer 12 from the layered body 10 obtained in the growth surface processing step S12. A known means (such as a wire saw and a band saw) may be used for the cutting in this step. The present invention is not limited to this embodiment where part of the aluminum nitride single crystal layer 12 is cut. For example, the base substrate 11 and the aluminum nitride single crystal layer 12 may be cut on the boundary therebetween. Alternatively, the layered body 10 may be separated into: the base substrate 11, and a layer that is at least part of the aluminum nitride single crystal layer 12 and that is layered over the base substrate 11; and any other part of the aluminum nitride single crystal layer 12; in other words, the aluminum nitride single crystal 12a may be separated from the base substrate 11.

In the separation step S13, prior to cutting, the layered body 10 is fixed to the jig 14 via the adhesive 13. At this time, the adhesive 13 is arranged on the supporting surface of the jig 14. Here, in the layered body 10, the face of the base substrate 11 which is the opposite to the side where the aluminum nitride single crystal layer 12 is layered is directed to come into contact with the adhesive 13. Here, in the separation step S13, the layered body 10 is fixed to the jig 14 in the same manner as in the growth surface processing step S12. Therefore, after the polishing in the growth surface processing step S12, the layered body 10 may be used in the separation step S13 without being removed from the jig 14. The fixing manner is not limited to this. One may remove the layered body 10 from the jig 14 after the growth surface processing step S12, and thereafter, reattach the layered body 10 to the jig 14.

In order to suppress crack formation following chipping of the periphery of the base substrate in cutting, one may cover the entire or part of the layered body 10 with a resin, a cement, or the like prior to cutting, and thereafter perform the cutting. At this time, a common epoxy resin, phenolic resin or wax may be used as the resin. After the layered body 10 is covered with the resin, the resin is cured by a common means such as curing by self-drying, thermosetting, and photo-setting, and thereafter, the cutting is carried out. As a cement as used herein, common industrial Portland cement, aluminous cement, or gypsum may be used.

The cutting in the separation is carried out parallel to the main face of the base substrate 11. When a wire saw 15 is used in the separation step S13, a wire saw with either fixed or free abrasive grains may be used as the wire saw 15. The tension of the wire is preferably adjusted properly, so that the thickness of a cutting margin is as thin as, for example, approximately 100 μm to 300 μm.

The cutting speed with the wire saw is properly adjusted, so that a residual distortion layer (damaged layer) to remain on the cut surface of the aluminum nitride single crystal layer 12 is thin, and so that the cutting direction is parallel to the main face. A relatively low speed is preferable as the condition. The speed is suitably within the range from 0.5 mm/h to 20 mm/h.

The wire of the wire saw 15 in the cutting may be oscillated. The wire may be successively or intermittently moved in the cutting direction. The oscillation of the wire in the cutting is properly controlled in order to prevent cracks from being formed due to heat generated by friction in the cutting.

In the cutting, the layered body 10 itself may be revolved. At this time, the speed of revolution of the layered body 10 is preferably within the range from 1 rpm to 10 rpm.

For the purposes of removing polycrystals formed on the periphery of the base substrate 11 and/or the aluminum nitride single crystal layer 12, and of shaping the periphery to be round, a peripheral grinding step may be introduced before or after the layered body 10 is cut. Also may be carried out is known substrate processing such as orientation flat marking, and beveling for exposing the crystal lattice plane or an inclined face on the end face of the periphery of the substrate.

The aluminum nitride single crystal 12a made from the aluminum nitride single crystal only can be obtained through this separation step S13. The aluminum nitride single crystal 12a is the original material of the aluminum nitride single crystal substrate 12b to be finally obtained.

The aluminum nitride single crystal 12a is provided with a cut surface S_{c} that is the opposite to the growth surface S_{g}′ after grinding or polishing. Here, the cut surface S_{c} has the shape including the deviation in the cutting, and a warp due to the Twyman effect in combination, and as a result, has a curved shape. The crystal lattice plane Sₖ curves due to the Twyman effect. At this time, the growth surface S_{g}′ after grinding or polishing curves so as to be kept parallel to the crystal lattice plane Sₖ. As a result, the aluminum nitride single crystal 12a has a curve shape as a whole.

In this step, preferably, the one face of the aluminum nitride single crystal 12a (in the example shown in FIG. 1, this face is on the bottom side of the sheet, whereas this face may be either the front or back face) is formed by cutting and separating from the aluminum nitride single crystal layer 12 by the use of one cutting means (one wire or one band). The cut surface S_{c} can be processed so as to be parallel to the growth surface S_{g}′ or the crystal lattice plane Sₖ in the undermentioned cut surface polishing step S14 because, in the present invention, the other face of the aluminum nitride single crystal layer 12 (in the example shown in FIG. 1, this face is on the top side of the sheet, whereas this face may be either the front or back face) is made so as to be kept parallel to the crystal lattice plane Sₖ, and thereby, the growth surface S_{g}′ after grinding or polishing, and the crystal lattice plane Sₖ are kept parallel even when the cutting causes the Twyman effect on the one face to curve the entire of the aluminum nitride single crystal layer 12.

### 1.4. Cut Surface Polishing Step S14

In the cut surface polishing step S14, the cut surface S_{c} of the aluminum nitride single crystal 12a obtained in the separation step S13 is polished to be flattened. When a large thickness difference is made in the separation step, or when flattening with higher accuracy is performed, grinding may be added before polishing.

In the cut surface polishing step S14, the aluminum nitride single crystal 12a is fixed to the jig 14 via the adhesive 13 prior to polishing, so that the growth surface S_{g}′ after processing is parallel to the supporting surface of the jig. A known method may be used as the fixing method. At this time, as can be seen from FIG. 1, the growth surface S_{g}′ after processing is arranged so as to be over the supporting surface of the jig 14, and thus, the aluminum nitride single crystal 12a is fixed, so that the growth surface S_{g}′ after processing is flat. As following this, the crystal lattice plane Sₖ also becomes flat. Therefore, in the posture where the aluminum nitride single crystal 12a is arranged on the jig 14, only the cut surface S_{c} is in a curved form.

The jig 14 and the adhesive 13 are as described above.

Known conditions may be used for polishing the cut surface S_{c} of the aluminum nitride single crystal 12a fixed to the jig 14. Such conditions may be considered in the same way as in the growth surface processing step S12.

After the polishing, the cut surface S_{c} is flattened to form a cut surface S_{c}′ after polishing.

The growth surface S_{g}′ after processing of the aluminum nitride single crystal 12a is polished when not polished in this situation. Known conditions may be used for this polishing. Such conditions may be considered in the same way as in the growth surface processing step S12.

This polishing leads to formation of the aluminum nitride single crystal substrate 12b from the aluminum nitride single crystal 12a, so that the aluminum single crystal substrate 12b can be obtained. As described later in detail, the growth surface S_{g}′ after processing, the crystal lattice plane Sₖ, and the cut surface S_{c}′ after polishing of the obtained aluminum nitride single crystal substrate 12b are parallel, and are flat even after the aluminum nitride single crystal substrate 12b is removed from the jig 14. Thus, the aluminum nitride single crystal substrate 12b with a warp of a much suppressed degree can be obtained.

### 1.5. Effect Etc.

By the producing method S10 a group III nitride single crystal substrate that has high parallelism between the surface and the crystal lattice plane, and such that a warp is difficult to form can be produced. More specifically, see the following.

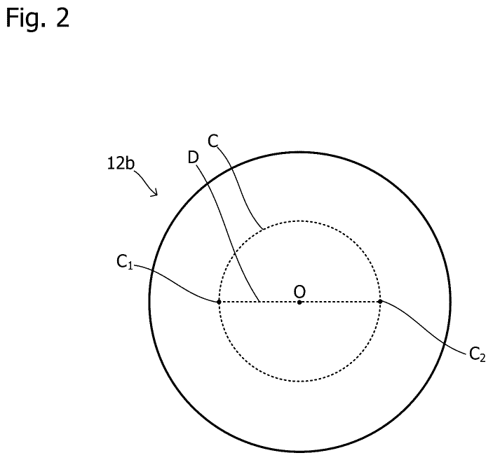

As shown in FIG. 2, when an imaginary circle C having the same center as the aluminum nitride single crystal substrate 12b, and a radius 0.6 to 0.85 times as long as that of the aluminum nitride single crystal substrate 12b in a plan view is assumed, the aluminum nitride single crystal substrate 12b has the following features based on the difference in height (positional difference in the thickness direction) between the two circumferential points C₁ and C₂ at one diameter D. That is, the difference (which may be referred to as the “difference between the differences in height”) between the difference in height between the points C₁ and C₂ at the growth surface S_{g}′ after processing (which may be referred to as the “surface difference in height”), and the difference in height between the points C₁ and C₂ at the crystal lattice plane (which may be referred to as the “crystal lattice plane difference in height”) is at most 15 μm. This means that the parallelism between the surface and the crystal lattice plane is high. Further, when the radius of curvature of the crystal lattice plane is at least 15 m, both the surface profile and the crystal lattice plane are in a flat state; and the radius of curvature thereof of at least 20 m is more preferable. One example of the relationship between the dimensions, and the measurement positions of the aluminum nitride single crystal substrate 12b is shown in table 1 below.

TABLE 1

| Aluminum nitride single crystal substrate 12b | | | Measurement position | |
|---|---|---|---|---|
| diameter | | radius | radius | proportion |
| (inches) | (mm) | (mm) | (mm) | — |
| 1 | 25.4 | 12.7 | 8 | 0.63 |
| 1.5 | 35.0 | 17.5 | 12 | 0.69 |
| 2 | 50.8 | 25.4 | 20 | 0.79 |
| 3 | 76.2 | 38.1 | 30 | 0.79 |
| 4 | 101.6 | 50.8 | 40 | 0.79 |

Here, the diffraction angles of the crystal lattice plane Sₖ parallel to the main face at the point C₁, the center O and the point C₂ are measured by XRD, R₁ and R₂ that represent the radii of curvature of the crystal lattice plane between the point C₁ and the center O, and between the point C₂ and the center O, respectively, are calculated, and the mean value of the calculated results is defined as the radius of curvature of the crystal lattice plane R. The crystal lattice plane difference in height can be obtained by converting the radius of curvature R. The difference between the diffraction angles at the point C₁ and the center O, and the difference between the diffraction angles at the point C₂ and the center O are defined as θ_{C1} and θ_{C2}, respectively.

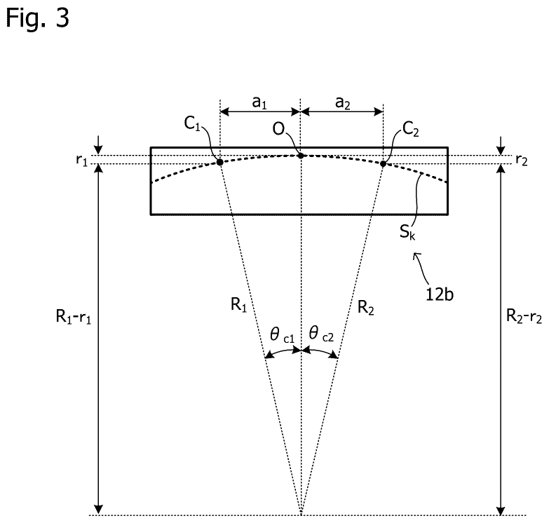

FIG. 3 schematically shows the aluminum nitride single crystal substrate 12b viewed from the side, and is a schematic view illustrating a conversion formula from which the radius of curvature of the crystal lattice plane, and the crystal lattice plane difference in height are derived. For convenience of the description, in FIG. 3, the crystal lattice plane Sₖ is drawn to have a convex curve on the top side of the sheet. The shape of the crystal lattice plane Sₖ is not limited to this. The crystal lattice plane Sₖ may have a convex curve on the bottom side of the sheet. It is also noted that the curved state is exaggeratedly shown compared to the thickness and the diameter for illustrating the relationship between the radius of curvature and the difference in height, but does not all correspond to an actual state.

The radius of curvature of the crystal lattice plane can be easily calculated by the following formulae.

$$radius of curvature {R}_{1} = ( length between point {C}_{1} and center O ) / sin ( {θ}_{C 1} )$$

$$radius of curvature {R}_{2} = ( length between point {C}_{2} and center O ) / sin ( {θ}_{C 2} )$$

$$radius of curvature R = ( radius of curvature {R}_{1} + radius of curvature {R}_{2} ) / 2$$

Here, θ_{C1} and θ_{C2} represent the amount of positional difference (°) in crystal lattice plane between the two points of the center O and the point C₁, and the two points of the center O and the point C₂, respectively.

The difference in height can be easily calculated by the following formulae using a trigonometric function. The difference in height r shall be the mean value of the difference in height r₁ and the difference in height r₂.

$$difference in height {r}_{1} = {R}_{1} ( 1 - cos ( {θ}_{C 1} ) )$$

$$difference in height {r}_{2} = {R}_{2} ( 1 - cos ( {θ}_{C 2} ) )$$

$$difference in height r = ( difference in height {r}_{1} + difference in height {r}_{2} ) / 2$$

### 2. Aluminum Nitride Single Crystal Substrate

The aluminum nitride single crystal substrate 12b obtained by the production method S10 etc. may be used as, for example, an aluminum nitride single crystal self-supporting substrate for forming electronic devices and light emitting device layers. A known method such as metal organic chemical vapor deposition (MOCVD), molecular beam epitaxy (MBE), and hydride vapor phase epitaxy (HVPE) may be used when electronic devices and light emitting devices layers are formed.

One may use the aluminum nitride single crystal self-supporting substrate as a new base substrate, and further grow an aluminum nitride single crystal layer over the substrate.

Preferably, the aluminum nitride single crystal substrate 12b specifically has the following form.

The difference between the differences in height of the aluminum nitride single crystal substrate 12b is preferably at most 15 μm. Further, when the radius of curvature of the crystal lattice plane is at least 15 m, both the surface profile and the crystal lattice plane are in a flat state; and the radius of curvature thereof of at least 20 m is more preferable. Such an aluminum nitride single crystal substrate can perform a high function as an aluminum nitride substrate with no warp.

As described above, the concentration of carbon contained as an impurity in the aluminum nitride single crystal substrate 12b is preferably at most 3×10¹⁷ atoms/cm³. The lower limit of the carbon concentration is not particularly limited, whereas is preferably 1×10¹⁴ atoms/cm³.

As described, the carbon concentration may be adjusted by a known method (for example, JP 5904470 B2). Formation (growth) of the aluminum nitride single crystal layer is more easily achieved by HVPE than by any other method of vapor phase growth.

The thickness of the aluminum nitride single crystal substrate 12b is preferably at least 250 μm. The thicker, the easier the operability with tweezers or the like is, and the lower the risk of breaking the aluminum nitride single crystal substrate is. Thereby, the aluminum nitride single crystal substrate 12b can fully function as a self-supporting substrate.

### EXAMPLES

Hereinafter the present invention will be described in detail with reference to examples. The present invention is not limited to the following examples.

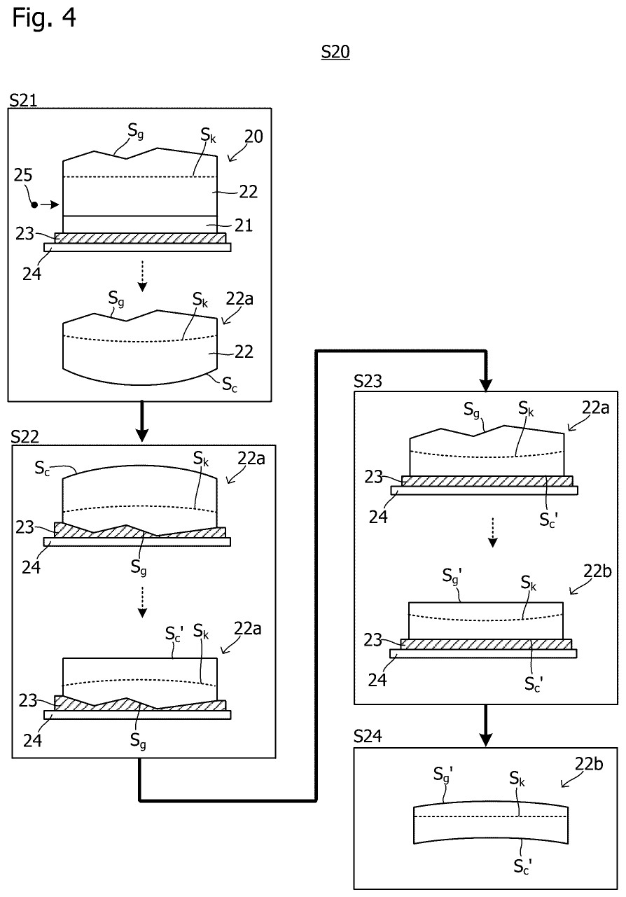

The inventors examined the difference between the differences in height in examples 1 to 4 where the aluminum nitride single crystal substrates 12b were produced according to the producing method S10 shown in FIG. 1, and comparative examples 1 and 2 where the aluminum nitride single crystal substrates 22b were produced according to the conventional producing method S20 shown in FIG. 4, and then, obtained the results as in table 2. In table 2, the positive value in each of “surface difference in height” and “crystal lattice plane difference in height” represents that the center of the substrate of the aluminum nitride single crystal 12b or 22b (hereinafter may be referred to as the “substrate center”) much warped (was in what is called a convex form), and the negative value therein represents that the substrate center less warped (was in what is called a concave shape). The “difference between the differences in height” is shown by the absolute value of the “surface difference in height”−the “crystal lattice plane difference in height”, and thus, takes a positive value.

### <Calculating Surface Difference in Height>

For the radius of curvature of the surface of each of the aluminum nitride single crystal substrates 12b and 22b (hereinafter may be simply referred to as the “substrates” with the reference signs omitted) of each of the examples, the radius of curvature of the surface which passed from the point C₁ through the substrate center O to the point C₂, and the surface difference in height obtained from the substrate center O, and the points C₁ and C₂ were calculated from a microscope image obtained by measuring the entire surface of the substrate by means of a white-light interferometric microscope (NewView 7300 manufactured by AMETEK, Inc.) with an object lens with a magnifying power of 10 by means of companion analysis software (MetroPro) of the device. The positive value of the surface difference in height represents that the substrate center much warped (was in what is called a convex shape), and the negative value thereof represents that the substrate center less warped (was in what is called a concave shape).

### <Calculating Crystal Lattice Plane Difference in Height>

In each of the examples, the radius of curvature of the crystal lattice place (crystal plane parallel to the main face) was calculated from the positional relationship between the peak positions (diffraction angles) of an X-ray omega rocking curve, and an optical system of X-ray irradiation: the X-ray omega rocking curve was measured by moving a stage from the center to the positions of the points C₁ and C₂ as using the substrate center as the position of 0 mm by means of a thin film X-ray diffractometer (X′Pert MRD manufactured by Malvern Panalytical) in combination with: a Ge(220) four-crystal monochromator module equipped with a ½° slit; and a Xe proportional counter. Thereafter, the crystal lattice plane difference in height was calculated from the calculated radius of curvature. The positive value of the crystal lattice plane difference in height represents that the substrate center much warped (was in what is called a convex shape), and the negative value thereof represents that the substrate center less warped (was in what is called a concave shape).

While the crystal lattice plane Sₖ is shown in each of FIGS. 1 and 4, an actual measured depth thereof was the vicinity (within 200 μm depending on the diffraction angle 2θ though) of the surface irradiated with an X ray. The value of the radius of curvature of the crystal lattice plane at the depth measured in any of the examples and the comparative examples was not largely different from that inside the substrate. Further, the substrate could be measured nondestructively by X-ray diffraction on the surface.

### <Calculating Flatness>

The flatness of the growth surface S_{g}′ after processing was measured and calculated using a dial gauge manufactured by Mitutoyo Corporation. Specifically, measured were the heights at five points at a straight line passing through the center on the growth surface S_{g}′ after processing. The flatness was calculated from the variations of the measured values.

### <Evaluation of Carbon Concentration>

For the concentrations of carbon contained in the aluminum nitride single crystal layers 12 and 22 according to each of the examples, quantitative analysis was performed by secondary ion mass spectrometry (SIMS measurement) (IMS-f6 manufactured by CAMECA) using a cesium ion at an acceleration voltage of 15 kV as a primary ion. The carbon atom concentration of a sample was quantitated by measuring the secondary ionic strength at a position 2 μm deeper from the surface side, and based on a calibration curve using a separately prepared AlN standard sample. The measurement limit by the SIMS measurement used in each of the examples and the comparative examples was 1×10¹⁶ (background level) atoms/cm³.

### Example 1

Example 1 was the example where the aluminum nitride single crystal substrate 12b by the producing method S10 shown in FIG. 1 was produced.

### S11: Preparation

An aluminum nitride single crystal substrate having a diameter of 50.8 mm, and a thickness of approximately 450 μm was used as the base substrate 11. The base substrate was disposed on a susceptor in an HVPE apparatus provided with a heating mechanism by high-frequency induction heating, so that the aluminum-polar face was a top face. Under the conditions that the substrate heating temperature was 1500° C., and the pressure inside a reactor was 500 Torr, 30 sccm of an aluminum trichloride gas, 250 sccm of an ammonia gas, and 16650 sccm of a nitrogen gas and a hydrogen gas in total as a carrier gas were circulated to grow an aluminum nitride single crystal layer over the base substrate. The growth time was 16 hours, and the aluminum nitride single crystal layer 12 of 860 μm to 1030 μm was layered. The diffraction angles at positions of the center, and the points 20 mm left and right apart from the center on the same crystal lattice plane of the obtained aluminum nitride single crystal layer 12 were measured. From the results of these diffraction angles, the radii of curvature R₁ and R₂ were calculated, and the radius of curvature of the crystal lattice plane R, and the crystal lattice plane difference in height r were calculated. As a result, the radius of curvature of the crystal lattice plane was −70 m, and the crystal lattice plane difference in height was 3 μm. The crystal lattice plane was almost parallel to the back face of the aluminum nitride single crystal layer 12.

### S12: Growth Surface Processing

The layered body 10 including the aluminum nitride single crystal layer obtained in “S11: Preparation” was fixed to the jig 14 with SHIFTWAX (registered trademark, manufactured by NIKKA SEIKO CO., LTD.). The growth surface S_{g} was ground, so that the growth surface S_{g}′ after processing had a textured surface and was parallel to the crystal lattice plane. The flatness of the growth surface S_{g}′ after processing was measured using a dial gauge manufactured by Mitutoyo Corporation, and was 4 μm in the state where the layered body was fixed to the jig with SHIFTWAX (registered trademark). Thereafter, SHIFTWAX (registered trademark) was dissolved in acetone, and the layered body 10 was released from the jig 14.

### S13: Separation

The aluminum nitride single crystal layer 12 obtained in “S12: Growth Surface Processing” was fixed with an epoxy resin, so that the growth surface S_{g}′ ground in “S12: Growth Surface Processing” was parallel to the supporting surface of the jig 14. The aluminum nitride single crystal layer 12 was cut in a direction parallel to the supporting surface of the jig by means of a wire saw using free abrasive grains so as to be separated into: the base substrate and a thin film that was part of the aluminum nitride single crystal layer and that was layered over the base substrate; and the aluminum nitride single crystal 12a that was any other part thereof. The cutting margin in the cutting was 280 μm, and the thickness of the aluminum nitride single crystal 12a was approximately 570 μm.

### S14: Cut Surface Polishing

The growth surface S_{g}′ of the layered body 10 including the aluminum nitride single crystal 12a obtained in “S13: Separation” was fixed to the jig 14 with SHIFTWAX (registered trademark). The cut surface S_{c} was subjected to flat face exposure by grinding saw marks of the cut surface S_{c}. Further, a distortion layer was removed by CMP.

Thereafter, the polished cut surface S_{c}′ was fixed to the jig 14 with SHIFTWAX (registered trademark), and a distortion layer of the processed growth surface S_{g}′ was removed by CMP. The thickness of the obtained aluminum nitride single crystal substrate 12b was approximately 405 μm.

Measured and analyzed was the surface difference in height of the obtained aluminum nitride single crystal substrate 12b between the positions 20 mm left and right apart from the center. Further, the radius of curvature of the crystal lattice plane R, and the crystal lattice plane difference in height were calculated in the same manner as in “S11: Preparation”. As a result, the surface difference in height was −4 μm, the radius of curvature of the crystal lattice plane was −1113 m, and the crystal lattice plane difference in height was 0 μm. Therefore, the difference between the surface difference in height and the crystal lattice plane difference in height was 4 μm.

The aluminum nitride single crystal layer was grown over the base substrate under the same conditions as in “S11: Preparation”. The carbon concentration of the obtained aluminum nitride single crystal layer 12 was evaluated by SIMS measurement, and was at most the background level. That is, the carbon concentration was at most 1×10¹⁶ atoms/cm³.

### Example 2

In example 2, the aluminum nitride single crystal substrate 12b was produced by the producing method S10 shown in FIG. 1 in the same manner as in example 1. The thickness of the aluminum nitride single crystal layer 12 obtained in “S11: Preparation” was 880 μm to 1130 μm, the radius of curvature of the crystal lattice plane was −82 m, and the crystal lattice plane difference in height was 2 μm.

The thickness of the aluminum nitride single crystal substrate 12b obtained in “S14: Cut Surface Polishing” was approximately 321 μm. The surface difference in height between the positions 20 mm left and right apart from the center was 5 μm, the radius of curvature of the crystal lattice plane was 154 m, and the crystal lattice plane difference in height was 1 μm. Therefore, the difference between the surface difference in height and the crystal lattice plane difference in height was 4 μm.

### Example 3

In example 3, the aluminum nitride single crystal substrate 12b was produced by the producing method S10 shown in FIG. 1 in the same manner as in example 1. The thickness of the aluminum nitride single crystal layer 12 obtained in “S11: Preparation” was 840 μm to 1180 μm, the radius of curvature of the crystal lattice plane was −122 m, and the crystal lattice plane difference in height was 2 μm.

The thickness of the aluminum nitride single crystal substrate 12b obtained in “S14: Cut Surface Polishing” was approximately 321 μm. The surface difference in height between the positions 20 mm left and right apart from the center was 6 μm, the radius of curvature of the crystal lattice plane was 267 m, and the crystal lattice plane difference in height was 1 μm. Therefore, the difference between the surface difference in height and the crystal lattice plane difference in height was 5 μm.

### Example 4

In example 4, a base substrate made in step S21 of comparative example 1 described later was used as a base substrate again by subjecting a cut surface thereof to CMP. The thickness was approximately 480 μm. The aluminum nitride single crystal substrate 12b was produced by the producing method S10 shown in FIG. 1 in the same manner as in example 1. The thickness of the aluminum nitride single crystal layer 12 obtained in “S11: Preparation” was 724 μm to 1190 μm, the radius of curvature was −108 m, and the crystal lattice plane difference in height was 2 μm.

The thickness of the aluminum nitride single crystal substrate 12b obtained in “S14: Cut Surface Polishing” was approximately 319 μm. The surface difference in height between the positions 20 mm left and right apart from the center was 10 μm, the radius of curvature of the crystal lattice plane was −305 m, and the crystal lattice plane difference in height was −1 μm. Therefore, the difference between the surface difference in height and the crystal lattice plane difference in height was 11 μm.

### Comparative Example 1

Comparative example 1 was the example where the aluminum nitride single crystal substrate 22b by the producing method S20 shown in FIG. 4 was produced.

### S21:

An aluminum nitride single crystal substrate having a diameter of 50.8 mm, and a thickness of approximately 450 μm was used as the base substrate 11. The conditions for growing the aluminum nitride single crystal layer over the base substrate were the same as in example 1. The thickness of the obtained aluminum nitride single crystal layer 22 was 830 μm to 1030 μm. The measurement and analysis were carried out under the same conditions as in example 1, and the positional difference in the crystal lattice plane at the positions 20 mm left and right apart from the center was measured. The radius of curvature of the crystal lattice plane was −67 m, and the crystal lattice plane difference in height was 3 μm.

The layered body 20 including the obtained aluminum nitride single crystal layer was fixed with an epoxy resin. The cutting conditions were the same as in example 1. The cutting margin in the cutting was 280 μm, and the thickness in the cutting was 550 μm to 740 μm.

### S22:

The layered body 22a including the aluminum nitride single crystal layer obtained in S21 was fixed with SHIFTWAX (registered trademark). Because the thickness difference in the growth surface S_{g} that was to be an adhered face to the jig was large, SHIFTWAX (registered trademark) was applied thicker than in the examples, and the layered body 20 was fixed so as not to be pressed down by the apparatus etc. The cut surface S_{c} was ground so as to be processed to have a textured surface. Thereafter, a distortion layer of the cut surface S_{c} was removed by CMP. The flatness of the cut surface S_{c}′ after processing was measured using a dial gauge manufactured by Mitutoyo Corporation, and was 8 μm in the state where the layered body was fixed to the jig with SHIFTWAX (registered trademark). Thereafter, SHIFTWAX (registered trademark) was dissolved in acetone, and the layered body 20 was released from the jig.

### S23:

The aluminum nitride single crystal 22a obtained in S22 was fixed to the jig 24 with SHIFTWAX (registered trademark). In the same manner as in S22, the growth surface S_{g}′ was flattened by grinding, and a distortion layer was removed by CMP. After the processing, SHIFTWAX (registered trademark) with which the aluminum nitride single crystal substrate 22b was fixed was dissolved in acetone, and the aluminum nitride single crystal substrate 22b was released from the jig.

### S24:

The thickness of the obtained aluminum nitride single crystal substrate 22b was approximately 361 μm. The measurement and analysis were carried out under the same conditions as in example 1. The surface difference in height between the positions 20 mm left and right apart from the center was 28 μm, the radius of curvature of the crystal lattice plane was −207 m, and the crystal lattice plane difference in height was −1 μm. Therefore, the difference between the surface difference in height and the crystal lattice plane difference in height was 29 μm.

The aluminum nitride single crystal layer was grown over the base substrate under the same conditions as in S11. The carbon concentration of the obtained aluminum nitride single crystal layer 22 was evaluated by SIMS measurement, and was at most the background level. That is, the carbon concentration was at most 1×10¹⁶ atoms/cm³.

### Comparative Example 2

In comparative example 2, the aluminum nitride single crystal substrate 22b was produced by the producing method S20 shown in FIG. 4 in the same manner as in comparative example 1. The obtained thickness of the aluminum nitride single crystal layer 22 just before S21 and before adhered to the jig was 860 μm to 1160 μm. The positional difference in the crystal lattice plane at the positions 20 mm left and right apart from the center was measured. The radius of curvature of the crystal lattice plane was −67 m, and the crystal lattice plane difference in height was 3 μm.

The thickness of the aluminum nitride single crystal substrate 22b obtained in S23 was approximately 365 μm. The surface difference in height between the positions 20 mm left and right apart from the center was 17 μm, the radius of curvature of the crystal lattice plane was −448 m, and the crystal lattice plane difference in height was 0 μm. Therefore, the difference between the surface difference in height and the crystal lattice plane difference in height was 17 μm.

Table 2 shows the results of each of the examples.

### Table 2

TABLE 2

| | | | difference in | | |
|---|---|---|---|---|---|
| | | | height (μm) | | difference |
| | | Radius of | | crystal | between |
| | Thickness | curvature | | lattice | differences |
| | (μm) | (m) | surface | plane | in height (μm) |
| Example 1 | 405 | −1113 | −4 | 0 | 4 |
| Example 2 | 321 | 154 | 5 | 1 | 4 |
| Example 3 | 321 | 267 | 6 | 1 | 5 |
| Example 4 | 319 | −305 | 10 | −1 | 11 |
| Comparative | 361 | −207 | 28 | −1 | 29 |
| example 1 | | | | | |
| Comparative | 365 | −448 | 17 | 0 | 17 |
| example 2 | | | | | |

As described, the producing method according to any embodiment of the present invention allows less formation of a warp.

### REFERENCE SIGNS LIST

10, 20 layered body
11, 21 base substrate
12, 22 aluminum nitride single crystal layer (group III nitride single crystal layer)
12a, 22a aluminum nitride single crystal (group III nitride single crystal)
12b, 22b aluminum nitride single crystal substrate (group III nitride single crystal substrate)
13, 23 adhesive
14, 24 jig
15, 25 wire saw

1. A method of producing a group III nitride single crystal substrate, the method comprising:
processing a face of a group III nitride single crystal layer of a layered body, so that the face is parallel to a crystal lattice plane, the layered body including a base substrate, and the group III nitride single crystal layer over the base substrate;
after said processing,
cutting and separating a group III nitride single crystal in a form of plate from the base substrate or the group III nitride single crystal layer, or
cutting and separating the base substrate and the group III nitride single crystal layer on an interface therebetween in a form of plate; and
after said cutting and separating, polishing a cut surface of the group III nitride single crystal, the cut surface being formed by said cutting.

2. The method according to claim 1, said processing comprising:
fixing the group III nitride single crystal, so that a radius of curvature of the crystal lattice plane is at least 15 m, and grinding a fixed growth surface of the group III nitride single crystal layer.

3. The method according to claim 1, wherein in said polishing, a face obtained by said polishing is parallel to the crystal lattice plane.

4. The method according to claim 1, wherein a radius of curvature of the crystal lattice plane of the layered body before said cutting and separating is at least 50 m.

5. The method according to claim 1, wherein
the group III nitride single crystal layer is an aluminum nitride single crystal layer, and
the face processed in said processing is an aluminum-polar face.

6. The method according to claim 1, wherein in said cutting and separating, the layered body is cut in the form of plate by means of one cutting jig.

7. An aluminum nitride single crystal substrate, wherein
difference between difference in height of a surface of the aluminum nitride single crystal substrate, and difference in height of a crystal lattice plane is at most 15 μm, the difference in height of a surface being calculated from a radius of curvature of the surface, the difference in height of a crystal lattice plane being calculated from a radius of curvature of the crystal lattice plane, and
a concentration of carbon contained as an impurity is at most 3×10¹⁷ atoms/cm³.

8. The aluminum nitride single crystal substrate according to claim 7, wherein the radius of curvature of the crystal lattice plane is at least 15 m.

9. The aluminum nitride single crystal substrate according to claim 7, wherein a thickness of the aluminum nitride single crystal substrate is at least 250 μm.

10. The aluminum nitride single crystal substrate according to claim 7, wherein the surface is an aluminum-polar face.
